(19) United States
(12) Patent Application Publication
(10) Pub. No.: US 2002/0108090 A1
(43) Pub. Date: Aug. 8, 2002

(54) Blind transport format detection of turbo-coded data

(75) Inventors: Meir Ariel, Tel Aviv (IL); Ofer Amrani, Tel Aviv (IL)

Correspondence Address: G.E. EHRLICH (1995) LTD., c/o ANTHONY CASTORINA, SUITE 207, 2001 JEFFERSON DAVIS HIGHWAY, ARLINGTON, VA, 22202, US

(73) Assignee: Cute Ltd.

(21) Appl. No.: 09/775,580

(22) Filed: Feb. 5, 2001

(51) Int. Cl. H03M 13/00; H03M 13/03

(52) U.S. Cl. 714/792

(57) ABSTRACT

An apparatus for blind transport format detection of a received turbo coded data signal is provided. The apparatus includes (a) a syndrome vector generator for generating syndrome vectors for each of at least two constituent codes of a first candidate turbo code; and (b) an error rate estimator for estimating an error rate of a received turbo coded data signal based on said syndrome vectors of at least one constituent code of the at least two constituent codes.

### FIELD AND BACKGROUND OF THE INVENTION

The present invention relates to blind transport format detection of turbo coded data and more particularly but not exclusively to blind transport format detection of turbo coded data for use in third generation wireless communications.

Third generation (3G) wireless telecommunications is being developed to provide mobile communication devices with the ability to provide a full range of voice and data services including multimedia. 3G is an umbrella standard that covers two major standards, Universal Mobile Telecommunications System (UMTS) and CDMA2000; the following description will use the terms and definitions of the UMTS format although it will be appreciated by the skilled person that the same may be applied to CDMA2000.

One of the ideas behind 3G is to provide a unified platform for efficient wireless transmission of different types of data such that a single infrastructure or device may support everything from a standard voice transmission to multimedia data.

Different types of data require different rates of transmission and different coding techniques. It is therefore necessary to provide the ability for sending and receiving equipment to be able to handle the full range of expected types of data format. In order to do this, it is necessary for a transmitter to be able to transmit different types of data in the most suitable format and for receivers to be able to identify the format and thus be able to receive the data appropriately. Transmission formats may typically comprise turbo codes, according to the UMTS standard.

In the UMTS standard, there is provided a transport format combination indicator (TFCI) field that provides information as to the format of the associated data frame.

In certain circumstances, the TFCI field may not be transmitted, or may be corrupted. In such cases, the receiver lacks certain information as to the format of the data and thus does not know how to decode the frame.

U.S. Pat. No. 5,936,972 describes a syndrome-based message structure determiner suitable for a transmission format based on convolutional codes. Convolutional codes are often used in wireless digital communication systems to protect transmitted information from error. In one type of variable message structure communication system, a transmitter selects one of n convolutional codes C₁, . . . , C. ᵢ, . . . , Cₙ to encode data. The receiver, however, generally does not know which message structure was selected by the transmitter and hence which convolutional code C was used by the transmitter.

In another type of variable message structure communication system, only a single convolutional code C is used, but the data transmission rate varies. For example, communication systems governed by the Interim Standard IS-95 specification adopted by the Telecommunications Industry Association (TIA) for Direct Sequence Code Division Multiple Access (DSCDMA) are capable of using variable data rate transmissions. The transmitter convolutionally encodes data at a certain data rate and then uses repetition to generate transmitted symbol sequences with uniform symbol rates. In such a system, however, the receiver generally does not know which message structure was selected by the transmitter and hence which data rate was used by the transmitter.

Aside from using different convolutional codes and various data transmission rates, different message lengths or different types of interleavers can be used to vary the particular message structure. In addition, variable properties may be combined; for example, different types of interleavers may also use various message lengths. Throughout, the receiver generally does not know at least one of the properties listed above and used by the variable message structure transmitter.

There are thus two categories of transport format detection available to the receiver: explicit transport format detection and blind transport format detection. In the explicit case, at the transmitter side format indicator bits may be encoded by an error correcting code (for example, in UMTS a (30,10) bi-orthogonal Hadamard code is used for protecting the TFCI field from error). At the receiver, the received version of the indicator field is decoded and then used to decide on the transport format combination. In the blind detection case, the indicator bits are either not transmitted, or they may be too corrupted to be decoded correctly. In this case the receiver detects the transport format combination using side information, e.g. received power ratio of DPDCH to DPCCH, cyclic redundancy check (CRC) results, etc.

In the case of a 3G downlink, conventional blind detection may be applied with convolutional coding as follows.

At the transmitter, the variable-rate data to be transmitted is block-encoded using a CRC error detection code and then convolutionally encoded. The receiver knows only the possible transport formats (or the possible end bit position).

The receiver performs Viterbi decoding on the soft decision sample sequence. The correct trellis path of the Viterbi decoder ends at the zero state at the correct end bit position.

Blind rate detection method (using CRC) traces back the surviving trellis path ending at the zero state (hypothetical trellis path) at each possible end bit position to recover the data sequence. Each recovered data sequence is then error-detected by CRC and if there is no error, the recovered sequence is declared as correct.

In order to reduce the probability of false detection (this happens if the selected path is wrong but the CRC misses the error detection), a path selection threshold is introduced. This threshold determines whether the hypothetical trellis path connected to the zero state should be traced back or not at each end bit position.

U.S. Pat. No. 5,936,972 describes an alternative solution for blind transport format detection. U.S. Pat. No. 5,936,972 proposes that if the bit error rate (BER) of a received vector could be estimated before soft-decision decoding the vector, the vector could be discarded or replaced before being processed by the computationally intensive Viterbi decoder. This provides the ability to estimate the quality of a received vector before the vector is soft-decision decoded.

In the case of convolutional, that is to say non-turbo, coding, the above-mentioned U.S. Pat. No. 5,936,972 uses syndrome vectors, calculated for hypothetical convolutional codes, in order to estimate the quality of a received signal in a variable message structure communication system. A digital signal from analog-to-digital converter is separated into multiple branching paths, one for each potential message structure type. In a single path, a digital demodulator demodulates the digital signal to produce a demodulated received signal. A deinterleaver deinterleaves the demodulated received signal, and a symbol-by-symbol detector hard-decision detects the deinterleaved signal. For each hard-decision vector, a syndrome calculator calculates a syndrome vector. The syndrome vector is analyzed by a syndrome error estimator having an associated syndrome pattern memory. A comparator analyzes error counter totals from each syndrome error estimator.

3G wireless communications standards propose the use of Turbo codes, in place of convolutional codes, for high-rate data services. Turbo codes are used in digital communication systems to protect transmitted information from error. Turbo coders are constructed with interleavers and parallel or serial concatenation of constituent codes, which are usually systematic convolutional codes, but can alternately be block codes. Future wireless telecommunications standards, such as UMTS (also called the 3GPP—third generation partnership project for wireless systems), employ an 8-state parallel-concatenated convolutional code with a block length of up to 5120 bits. Turbo decoding is iterative using a soft output decoder to decode the constituent convolutional code.

In 3G wireless communications standards, a Transport Format Combination Indicator (TFCI), as described above, is used to inform the receiver of the number of bits in each frame of each of the services currently in use. As soon as a certain bit-rate is known, the number of code channels, the spreading factor and the puncturing/repetition rate are immediately known.

The decoding of turbo-coded data is based on a maximum a posteriori criterion with iterative decoding, rather than maximum likelihood decoding. Consequently, the Viterbi/CRC method for blind detection of the transport format described above, as discussed above, which is based on maximum likelihood, is not applicable. In addition, since the concept of syndrome is not defined in case of turbo codes, U.S. Pat. No. 5,936,972 is also not applicable to turbo codes.

In order to select between different candidate transport formats in a receiver of a variable message structure system with turbo coded data, a received signal is demodulated in parallel using each of the possibly transmitted message structures. Parallel turbo decoders, based on the maximum a posteriori (MAP) criterion, decode the parallel demodulated vectors. The decoded vector which satisfies the CRC is then selected as the properly decoded signal. Alternatively, the decoded vector with the lowest BER is selected.

A receiver employing the above-described decoding method is wasteful of resources. Practical turbo decoder, such as Log-MAP or Max-Log-MAP decoders, are computationally complex, and their complexity increase linearly with increasing number of states of the turbo code. This essentially means that a turbo decoder requires a significant amount of current and a processing capability of many millions of instructions per second (MIPS). For variable message structure decoding, as described in the preceding paragraph, multiple turbo decoders are required, and this increases the computational complexity by yet another level.

There is thus a widely recognized need for, and it would be highly advantageous to have, a reliable blind transport format combination detector with reduced complexity for use in turbo-coded data transmission systems.

### SUMMARY OF THE INVENTION

Broadly, a preferred embodiment of the invention provides a system in which a receiver receives a turbo-coded signal of unknown type. The signal type may be unknown because it was never recorded. Alternatively, the format information may have been lost due to distortion in the channel. Thus a received signal of unknown format is turbo-decoded, possibly in parallel, using a range of possible transport formats. The result that satisfies the CRC check or, alternatively, indicates the lowest bit error rate (BER) is interpreted as the correctly decoded signal.

Preferably, the input BER to the decoder is estimated by calculating syndrome vectors corresponding to the constituent convolutional or block codes for the respective data type or turbo code being tested. A bit error rate is then estimated for each set of constituent codes, which is to say, for each candidate turbo code.

Thus, according to one aspect of the present invention there is provided an apparatus for blind transport format detection of a received turbo coded data signal, the turbo code encoding the data signal being decomposable into at least two constituent codes, the apparatus comprising: (a) a syndrome vector generator for generating syndrome vectors for each of the at least two constituent codes of a first candidate turbo code; and (b) an error rate estimator for estimating an error rate of a received turbo coded data signal based on the syndrome vectors of at least one constituent code of the at least two constituent codes.

According to further features in preferred embodiments of the invention described below, the apparatus further comprising: (c) an adder for summing estimated error rates of the at least two constituent codes to thereby produce a first estimated error rate for the first candidate turbo code; and (d) a selector for comparing the first estimated error rate of the first candidate turbo code with a second estimated error rate of a second candidate turbo code and for selecting a candidate turbo code of the first and second turbo codes having a lowest estimated error, the candidate turbo code selected being utilizable for decoding the turbo-coded data signal.

According to still further features in the described preferred embodiments the second estimated error rate of a second candidate turbo code is obtained via turbo decoding.

According to still further features in the described preferred embodiments the apparatus further comprising a symbol by symbol detector for detecting the received turbo coded data signal symbol-wise for error estimation.

According to still further features in the described preferred embodiments the apparatus further comprising a thresholder for comparing the lowest estimated error rate against a threshold and if the threshold is exceeded then not selecting the turbo-code having the lowest estimated error rate for decoding the received signal.

According to still further features in the described preferred embodiments the apparatus further comprising a decomposer operable to decompose each symbol detected by the symbol by symbol detector into a symbol pair, each member of the pair corresponding to a different one of the at least two constituent codes.

According to still further features in the described preferred embodiments the apparatus further comprising at least one pair of syndrome calculators operable to calculate a pair of the syndrome vectors based on the decomposed symbols output by the symbol by symbol detector and on an associated pair of parity check matrices.

According to still further features in the described preferred embodiments the apparatus further comprising at least one pair of syndrome error estimators having at least one predetermined error pattern and further having a comparator operable to compare the at least one predetermined error pattern with the syndrome vector pair to produce an estimate of a bit error rate.

According to another aspect of the present invention there is provided a method of blind transport format detection of a received turbo coded data signal comprising the steps of: (a) receiving a turbo-coded data signal; (b) detecting symbols from the data signal; (c) decomposing the signals into signal pairs; (d) determining syndrome vectors for each detected signal of the pair based on at least two candidate turbo-codes; (e) comparing each syndrome vector with error patterns and thereby determining a bit error rate for each candidate turbo code; and (f) selecting a candidate turbo code having a lowest bit error rate for decoding the data signal.

According to still further features in the described preferred embodiments the method further comprising a step of comparing the lowest bit error rate selected against a threshold and if the threshold is exceeded then not selecting the candidate turbo code associated therewith for decoding the received signal.

According to still further features in the described preferred embodiments the step of calculating the pair of syndrome vectors is carried out based on the decomposed symbols output by the symbol by symbol detector and on an associated pair of parity check matrices.

According to still further features in the described preferred embodiments the error patterns are predetermined error patterns and wherein the method further comprises a step of comparing the at least one predetermined error pattern with the syndrome vector pair to produce an estimate of a bit error rate.

According to yet another aspect of the present invention there is provided a method of blind transport format detection of a received turbo coded data signal comprising the steps of: (a) receiving a turbo-coded data signal; (b) detecting symbols from the data signal; (c) decomposing the signal into a pair of signals; (d) determining syndrome vectors for each signal of the pair of signals based on a first candidate turbo-code; and (e) estimating an error rate of the turbo coded data signal based on the syndrome vectors of at least one signal of the pair of signals.

According to still further features in the described preferred embodiments the method further comprising: (f) summing the error rates of pair of signals to thereby produce a first estimated error rate for the first candidate turbo code; (g) comparing the first estimated error rate of the first candidate turbo code with a second estimated error rate of a second candidate turbo code; and (h) selecting a candidate turbo code of the first and second turbo codes having a lowest estimated error, the candidate turbo code selected being utilizable for decoding the turbo-coded data.

According to still further features in the described preferred embodiments encoding of the turbo coded data signal includes interleaving and concatenation.

According to still further features in the described preferred embodiments a turbo code of the turbo coded data signal includes at least two constituent codes.

According to still further features in the described preferred embodiments a constituent code of the at least two constituent codes is a convolutional code or a block code.

According to still further features in the described preferred embodiments the constituent code is an 8-state convolutional code with a block length of up to 5120 bits.

According to still further features in the described preferred embodiments the at least two candidate turbo codes are each associated with a different predetermined bit rate.

According to still further features in the described preferred embodiments the error patterns are predetermined error patterns and wherein the method further comprises a step of comparing the at least one predetermined error pattern with the syndrome vector pair to produce an estimate of a bit error rate.

According to still further features in the described preferred embodiments the second estimated error rate of a second candidate turbo code is obtained via turbo decoding.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a generalized block diagram of a communication system having a blind TFCI detector according to a preferred embodiment of the present invention;

FIG. 2 is a generalized block diagram of the blind TFCI detector of FIG. 1 according to a preferred embodiment; and

FIG. 3 is a simplified flow chart of the operation of the syndrome error estimators shown in FIG. 2 according to a preferred embodiment.

### DESCRIPTION OF THE PREFERRED EMBODIMENTS

The present invention is of an apparatus and method which can be used for blind transport format detection of turbo coded data.

The present invention can also be used to estimate the bit error rate (BER) of a received vector before sending it to the turbo decoder. Based on such BER estimation, the receiver could decide to discard the received vector due to too many transmission errors, or ask for retransmission of the vector before processing it by the computationally intensive turbo decoder.

The principles and operation of the present invention may be better understood with reference to the drawings and accompanying descriptions.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

Turbo codes typically include two constituent convolutional or block codes. A preferred embodiment of the present invention introduces the concept of syndrome into turbo codes, for accomplishing blind detection of the transport format combination. This is based on the observation that the selection of the transmission rate out of n possible rates at the transmitter and the application of the corresponding rate matching algorithm is equivalent to selecting one of n turbo codes C₁, . . . , Cᵢ, . . . , Cₙ to encode the data.

Aside from using different rates of turbo coded data and various data transmission rates, different message lengths or different types of interleavers may have been used to vary the particular message format. The receiver, however, generally does not know which transport format was selected by the transmitter or, equivalently, which turbo code was used by the transmitter to encode the data.

At the receiver, the blind transport format detector of the present invention first demodulates the received signal according to various transport formats that are usable by the variable transport format communication system. This is followed by calculating a pair of syndrome vectors for each candidate turbo code. The two syndrome vectors in the pair correspond respectively to the two constituent convolutional or block codes composing the candidate turbo code. Each pair of syndrome vectors is used to form an estimation of the BER of the received signal. The transport format combination that corresponds to the lowest BER estimation is selected as the correct format combination and full decoding using the computationally intensive turbo decoder is now carried out.

Alternatively the BER estimated from a first candidate code via the method of the present invention as described herein (using a single pair of syndrome vectors) can be compared with BER of a second candidate code estimated via any suitable prior art method, such as for example, turbo decoding to thereby select the transport format combination that corresponds to the lowest BER.

Following is a detailed description of the method of the present invention as used in blind TFCI detection of a received turbo encoded data signal.

Let r₁, . . . , rᵢ, . . . , rₙ denote received signals demodulated according to various demodulation schemes that are usable by the communication system. Then each vector rᵢ is a vector of real numbers of length Nᵢ. Let vᵢ denote the vector obtained by the symbol-by-symbol detection of demodulated received signal vector rᵢ. Since the detected hard-decision symbols are binary, vᵢ is a binary vector of length Nᵢ having element values of either 0 or 1.

Furthermore, let us denote vᵢ=cᵢ₊ₑᵢ, where cᵢ is the transmitted turbo coded vector, and eᵢ is the transmission error vector. It is pointed out that the bits of cᵢ are all either information bits or parity check bits from the first constituent code or parity check bits from the second constituent code. Consequently, cᵢ may be decomposed into two code vectors cᵢ₁ and cᵢ₂ each corresponding to one of the two constituent codes. More specifically, cᵢ₁ comprises all the information bits of the turbo code vector and all the parity check bits from the first constituent code, whereas cᵢ₂ comprises the interleaved information bits of the turbo code vector and the parity check bits from the second constituent code. Accordingly, all constituent and related vectors may likewise be decomposed down into two related vectors.

For each potential turbo code C₁, . . . , Cᵢ, . . . , Cₙ there exists a pair of scalar parity check matrices (H_{1,1,} H_{1,2}) . . . , (H_{i,1},H_{i,2}) . . . , (H_{n,1,} H_{n,2}) associated with its constituent codes. Each parity check matrix thus has Mᵢⱼ columns and Nᵢⱼ rows where j=1, 2. The parity check condition that satisfies the constituent convolutional code vector cᵢⱼ is expressed by the relationship Hᵢⱼcᵢⱼ^{t}=0, where superscript t denotes vector transposition. In other words, if cᵢⱼ is a code vector belonging to a constituent convolutional code, then Hᵢⱼ cᵢⱼ^{t}=0, where superscript t denotes vector transposition.

A syndrome vector sᵢⱼ is a binary vector of length Mᵢⱼ defined as:

sᵢⱼ=Hᵢⱼvᵢⱼ^{t}.

Since vᵢⱼ=cᵢⱼ+eᵢⱼ, we have sᵢⱼ=hᵢⱼ(cᵢⱼ+eᵢⱼ)^{t}. Also, since Hᵢⱼcᵢⱼ^{t}=0, it follows that sᵢⱼ=Hᵢⱼeᵢⱼ^{t}.

When a syndrome vector is equal to zero, the most likely transmission error vector eᵢⱼ associated with the constituent convolutional code is equal to zero. When syndrome vector sᵢⱼ is not equal to zero, a transmission error is thereby inferred.

A non-zero syndrome vector is further able to identify a coset of the constituent code, which coset contains all possible error vectors in the detected signal vector vᵢⱼ. Under the maximum likelihood hard decision criterion, the most likely error vector is the member of the coset known as the coset leader, that is the coset member with the minimum Hamming weight. Consequently, a non-zero syndrome vector can be used to estimate the BER by taking the Hamming weight of it's coset leader as a lower bound on the number of errors that actually occurred during transmission. Different pairs of syndrome vectors may be constructed for the different possible transmission formats and the transmission format corresponding to the lowest bit error rate may be selected as the correct transmission format, all this without actually carrying out turbo decoding. In addition, the minimum BER thus determined may be utilized to reject the signal altogether as being too unreliable.

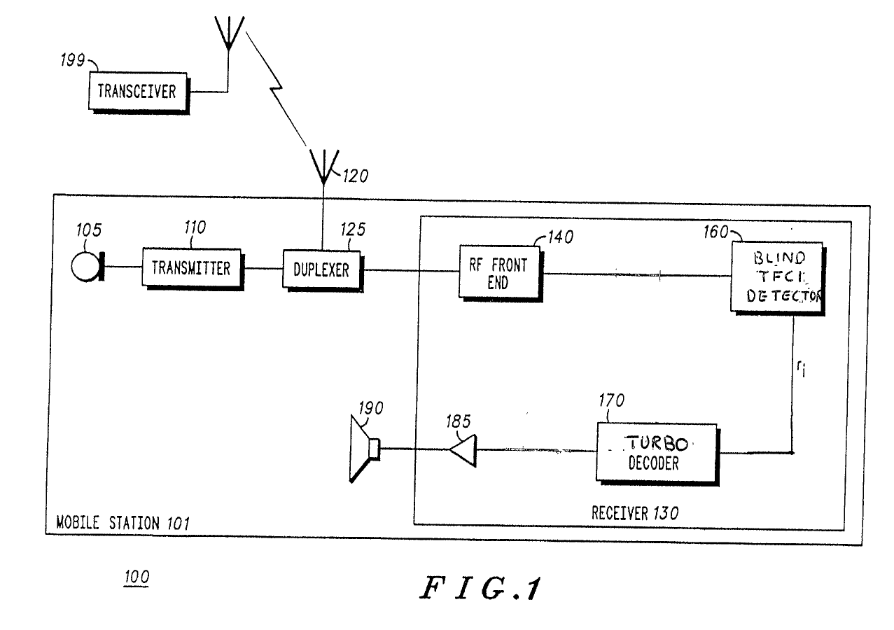

Reference is now made to FIG. 1, which is a generalized block diagram showing detection electronics 100 according to a preferred embodiment of the present invention. A receiver 130 is shown as part of a cellular mobile station 101, however, the receiver may alternately be part of a facsimile machine, modem, two-way radio, or other communication device that receives turbo-encoded encoded signals. In the mobile station 101, a microphone 105 picks up audio signals which are then modulated by a transmitter 110 and broadcast by an antenna 120 through a duplexer 125. The antenna 120 also receives radio frequency (RF) signals from a complementary transmitter in a transceiver 199 such as a cellular base station. In the receiver 130, an RF front end 140 steps down the received RF signal to a baseband signal.

Preferably, the baseband signal is a digital signal, as in the case of 3G if not, then an A/D converter may be inserted at this point.

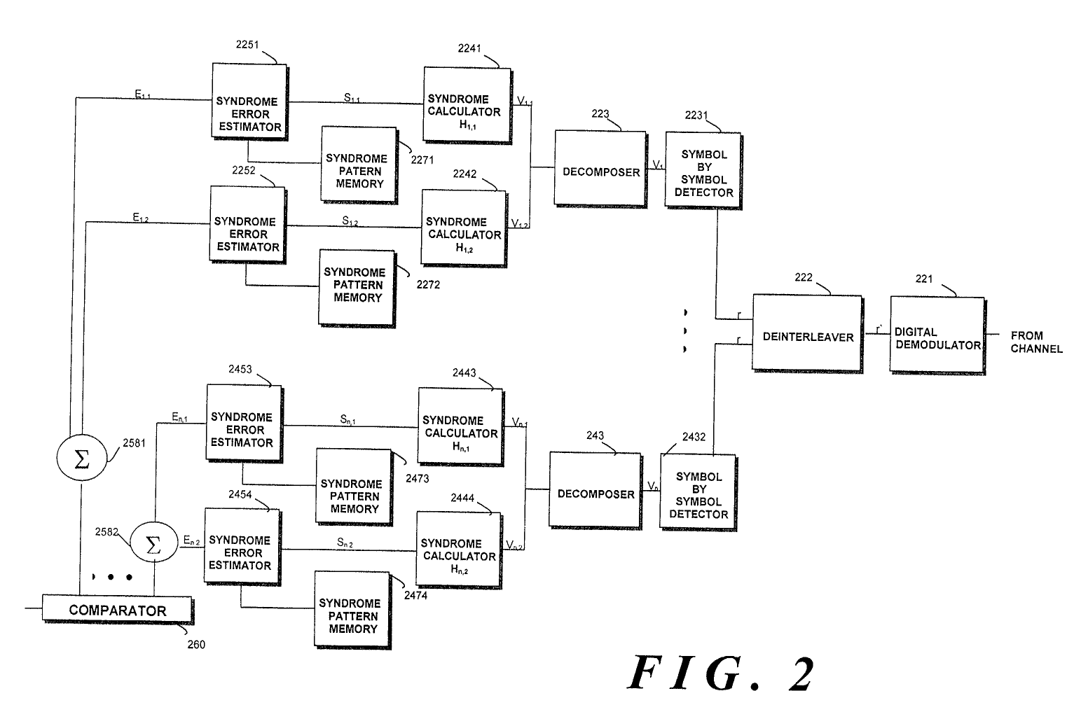

The digital signal is connected to a blind TFCI detector 160 which will to be explained in further detail with reference to FIG. 2. Blind TFCI detector 160 selects the message structure which in this case, is the turbo code most likely to have been used by the transmitter.

The demodulated received signal vector rᵢ is then sent to a turbo-decoder 170 where it is decoded using the turbo code selected by blind TFCI detector 160. The decoded signal may be a multimedia signal or it may be data, voice, or any other kind of signal that can be transmitted.

At the output of turbo-decoder 170, an audio amplifier 185 is shown for audio output. The audio amplifier uses operational amplifiers to increase the gain of the recovered signal for reproduction through audio speaker 190. Other types of output are treated in the appropriate manner, as will be clear to the skilled person.

Reference is now made to FIG. 2, which is a generalized block diagram showing two of a plurality of paths within blind TFCI detector 160 of FIG. 1. In a variable message structure turbo coding environment, blind TFCI detector 160 uses syndrome vectors to estimate the BER of symbol-by-symbol detected data to ascertain the received signal quality and determine the most likely transmitted message structure. In this embodiment, the transmitted message structure can be varied in length, type of interleaving, source data rate, turbo-code used or constituent convolutional or block code used in the turbo code and any combination of the above. This embodiment may also be modified to allow only certain properties to be varied or only allow certain combinations of the above properties to be varied.

Blind TFCI detector 160 preferably ascertains the most likely message structure of the transmitted signal and communicates the corresponding demodulated received signal rᵢ to turbo-decoder 170 for use in turbo decoding. In a preferred embodiment of the present invention, the digital signal is separated into m branching paths where m is the number of potential message structure types. Each branching path later splits into two, one for each of the pairs of constituent codes.

In the more general case, the digital signal from the direction of RF front end 140 is separated into 1×m×n branching paths, one for each potential message structure type, with 1 being the number of potential demodulators, m being the number of potential interleavers, and n being the number of potential turbo codes. Again, each branching path later splits into two, one for each of the pairs of constituent codes. For simplicity, we shall assume hereafter that 1=m=1, unless otherwise stated.

In each path, a digital demodulator 221 demodulates the digital signal to produce a demodulated received signal r′. A parallel deinterleaver 222 processes the demodulated received signal to produce multiple reordered received signals r. The block length is often coupled with the interleaver type, and thus different deinterleavers 222, in different paths, may produce a different block length.

Parallel symbol-by-symbol detectors 2231, . . . , 2432 detect the multiple reordered received signals to produce hard-decision vectors vᵢ. The hard decision vectors vᵢ are decomposed in a decomposer 223, . . . 243 into vector pairs v_{i,1}, v_{i,2} for the constituent codes, the vector pairs being passed to respective ones of pairs of syndrome calculators 2241, . . . 2444, and syndrome error estimators 2251, . . . , 2454.

Each symbol-by-symbol detector 2231, . . . 2432, merely examines the incoming signal without regard for the value of the surrounding symbols to produce the hard-decision vectors. Because each symbol-by-symbol detector is identical, the individual symbol-by-symbol detectors 2231, . . . , 2432 may be implemented using a single time-shared symbol-by-symbol detector. Each decomposed hard-decision vector vᵢⱼ is multiplied by parity check matrices H_{1,1}, H_{1,2}, . . . , H_{i,1}, H_{i,2} . . . , H_{n,1}, H_{n,2} in parallel syndrome calculators 2241, 2242, 2243, . . . , 2443, 2444 to produce 2×n syndrome vectors s_{1,1}, S_{1,2}, . . . , s_{i,1}, s_{i,2}, . . . , s_{n,1}, s_{n,2}.

Each syndrome vector is separately analyzed in one of parallel syndrome error estimators 2251, . . . , 2454 for the presence of syndrome patterns. Known syndrome patterns related to each parity check matrix are stored in syndrome pattern memories 2271, . . . , 2474 along with their associated Hamming weights βₚ. The Hamming weight βₚ of the most likely error pattern eₚ that could have been the cause for syndrome pattern p is defined as the minimum among all the cardinalities of the possible error patterns.

The Hamming weights of each syndrome pattern found in a syndrome vector are added together in syndrome error estimators 2251, . . . , 2454 to estimate the BER for each potential turbo code. Comparator (also referred to herein as selector) 260 compares summed error counter totals from different paths for syndrome error estimator pairs 2251, . . . , 2454, which are summed together by adders 2581, . . . , 2582. The demodulated received signal rᵢ corresponding to the lowest error counter total is then given to the turbo-decoder 170 (FIG. 1). If the difference between the lowest error count total and the second lowest error count total is not significant, or if all the error counts are above a given threshold value, then the received signal is judged to be unreliable, probably due to too many transmission errors. In this case, the vector is transferred to a higher decision level and not processed by the turbo-decoder 170 (shown in FIG. 1). Note that if the candidate turbo codes have different lengths, as in UMTS, then the error counter values must be normalized by the comparator 260 before the comparison can be completed.

The preferred embodiment shown in FIG. 2 can be easily tailored to the type of communication system being implemented. For example, if all the potential turbo codes have the same block length and same interleaving then there is only one possible sequence of hard-decision vectors v as determined by a single digital demodulator, deinterleaver, and symbol-by-symbol detector, but still as many distinct syndrome vectors as parity check matrices. Thus, under these circumstances, separate digital demodulators 221, could be replaced by a single digital demodulator, deinterleaver 222 would only produce one output r, and only a single symbol-by-symbol detector 2231 would be needed. The separate syndrome calculator pairs 2241, 2242 and syndrome error estimator pairs 2251, 2252 with corresponding syndrome pattern memories 2271, 2272, however, would remain distinct.

For a communication system with no interleaving where the block length changes but the turbo-codes remain constant, the longest possible demodulated received signal r contains information relating to the shorter possible block lengths. Thus, in this case, blind TFCI detector 160 can simply calculate a single, longest possible syndrome vector from the longest possible demodulated received signal and its associated parity check matrix. The longest possible syndrome vector can then be truncated according to the potential block lengths and analyzed for errors. The multiple digital demodulators, symbol-by-symbol detectors, and syndrome calculator pairs can each be replaced by a single element, and the multiple deinterleavers can be removed from the message structure determiner. The output of the syndrome calculator pairs would then feed subsets of the longest possible syndrome vector to multiple syndrome error estimators for signal quality analysis. Still other combinations of the variable properties of message structures can be made and implemented in blind TFCI detector 160.

Furthermore, if the communication system transmitter only changes, for example, the interleaver type at certain intervals, a proper deinterleaver which is determined by a message structure determiner can be used, dynamically, to degenerate blind TFCI detector 160 into a branch having only one deinterleaver during the remainder of the constant interleaver type interval. This interval or dynamic degeneration can be used to simplify blind TFCI detector 160 to reduce the number of branches and thus the computational complexity from the case shown in FIG. 2.

As described above, the detector has a plurality of parallel digital demodulators 221, one per each candidate turbo code, and each optimized to a potential transport format combination. Symbol-by-symbol detector 2231, . . . , 2432, initially detects each demodulated received signal to produce a symbol-by-symbol detected vector vᵢ. which can then be decomposed into a vector pair (v_{i,1}, v_{i,2}). Parallel syndrome calculator pairs 2241 . . . , 2444, compute pairs of syndrome vectors for each potential turbo code using the symbol-by-symbol detector's outputs (v_{i,1}, v_{i,2}) and an associated pair of parity check matrices (H_{i,1}, H_{i,2}). Then, parallel syndrome error estimators 2251 . . . 2454, compare known syndrome error patterns to the syndrome vectors generated in order to identify errors in the symbol-by-symbol detected vectors and approximate the BER of the received signal. The two BER approximations corresponding to the pair (v_{i,1}, v_{i,2}) are summed to produce a single BER approximation corresponding to one of candidate turbo codes Cᵢ. The BER corresponding to the correctly detected signal may be expected to be considerably lower than the BERs corresponding to the other detected signals, and the transport format or turbo code corresponding to this lowest BER is selected and preferably sent to the corresponding turbo decoder 170 and used for decoding the incoming signal.

Variations on blind transport format detector 160 include parallel deinterleavers inserted between the parallel demodulators and the symbol-by-symbol detectors for use in variable interleaver communication systems. Other variations include the collapsing of parallel demodulators or deinterleavers into a single demodulator or deinterleaver, or the expansion of a single symbol-by-symbol detector or syndrome calculator into parallel symbol-by-symbol detectors or syndrome calculators, depending on whether parallel computations are required.

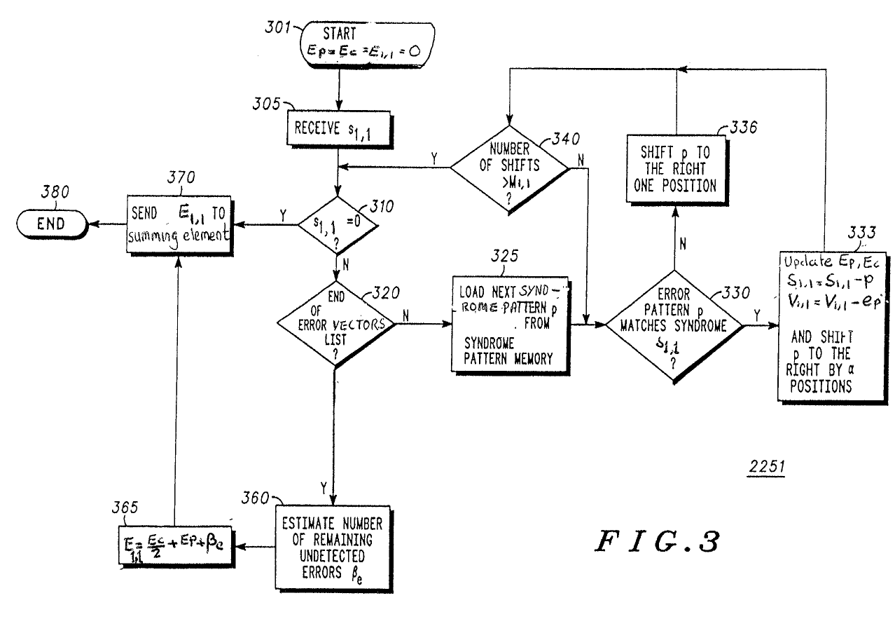

Reference is now made to FIG. 3 which is a generalized flow diagram illustrating operation of the syndrome error estimator shown in FIG. 2. Syndrome error estimator 2251 is shown as an example; each syndrome error estimator pair 2251, . . . , 2454 shown in FIG. 2 preferably operates in a similar manner.

During a start step 301, whilst at the beginning of the vector, the error counters E_{1,1}, Eₚ and E_{c} associated with syndrome error estimator 2251 are reset to zero. In step 305, the syndrome error estimator 2251 receives a syndrome vector s_{1,1} from its associated syndrome calculator 2241. If, at this time, the syndrome vector s_{1,1} is equal to zero, as determined in step 310, then the vector v_{1,1} corresponding to the scalar parity check matrix H_{1,1} used by the syndrome calculator 2241 is, to a high level of probability, the correct part c_{1,1} of transmission code vector c₁ . Then, the error counter value E_{1,1}=0 is sent to the summing element or adder 224 (shown in FIG. 2) in step 370, and the error estimate procedure is ended in step 380. If the syndrome vector s_{1,1}≠0 as determined in step 310, the syndrome error estimator 2251 searches through the syndrome vector s_{1,1} for known syndrome patterns p. This search is performed in several iterations. At the first iteration, step 320 searches only for the syndrome patterns corresponding to isolated single-symbol errors in the hard-decision vector v_{1,1}. It is noted that syndrome vector s_{1,1} is a linear combination of the columns of the parity check matrix H_{1,1} and, in the binary case, merely a sum of columns of H_{1,1}. A single error in a hard-decision detected vector v_{1,1} produces a syndrome vector which equals the corresponding column of the parity check matrix H_{1,1}. On the other hand, if multiple hard-decision errors are clustered, then their corresponding single-error syndrome patterns will overlap to generate a multiple-error syndrome pattern that can no longer be easily identified.

Due to the structure of parity check matrices, there is a limited number of syndrome patterns that correspond to single-symbol hard-decision errors. For instance, the scalar parity check matrix of a rate half binary constituent convolutional code contains only two types of syndrome patterns that correspond to single-symbol hard-decision errors. In other words, all the columns of this type of parity check matrix are shifted versions of the first two columns. For punctured constituent convolutional codes, the number of different syndrome patterns that correspond to single-symbol hard-decision errors is greater than for non-punctured codes, but still it is usually small enough to enable a relatively simple implementation of a message structure determiner.

Step 325 loads the next syndrome pattern p from an associated syndrome pattern memory 2271 (shown in FIG. 2). Decision step 330 looks for a match between the syndrome pattern p as initially loaded and the syndrome vector s_{1,1}. If the syndrome vector does not match the loaded syndrome pattern, step 336 shifts the error pattern p to the right by one bit. Step 340 makes sure that the syndrome pattern p has not been shifted farther than the length M_{1,1}, of the syndrome vector and continues to compare shifted versions of the syndrome pattern p to the syndrome vector s_{1,1}.

If the syndrome pattern p matches a syndrome vector segment, then an error pattern eₚ is detected. Consequently, in step 333 the error counters Eₚ and E_{c} are updated according to the position of the detected error. If the detected error is in the information part of v_{1,1}, then E_{c} is incremented by 1. If the detected error is in the parity part of v_{1,1}, then Eₚ is incremented by 1. If the detected eₚ indicates more than one error, than Eₚ and E_{c} are updated accordingly. The syndrome vector s_{1,1} is then modified to remove the syndrome pattern p, the hard-decision vector v_{1,1} is modified to remove the error pattern eₚ associated with the syndrome pattern, and the syndrome pattern is shifted to the right by α<M_{1,1} where α is the bit length of the syndrome pattern p.

If, after all the known error syndrome patterns have been removed from the syndrome vector, the modified syndrome vector still does not equal zero, the syndrome error estimator roughly estimates the Hamming weight βₑ of the remaining undetected errors in step 360. This estimation of βₑ is based on the lengths of the remaining undetected syndrome pattern as determined by computer simulations and experimental data. Obviously, a larger number of stored known syndrome patterns increases the accuracy of the blind TFCI detector at the cost of increased computational complexity.

A preferred estimation procedure of βₑ assumes that any remaining errors have a Hamming weight equivalent to half the length of the remaining syndrome patterns multiplied by the length of the hard-decision vector and then divided by the total length of the syndrome vector. For example, if the remaining syndrome patterns are thirty percent of the length of the syndrome vector, the estimated Hamming weight of the remaining errors is 0.5×0.3×F, where F is the number of bits in the hard-decision vector v_{1,1} Alternately, a simpler estimation can be based on the percentage of non-zero bits in the syndrome vector.

Step 365 increments E_{1,1} by the estimated error counts as follows: E_{1,1}=E_{c}/2+Eₚ+βₑ. The value of error counter E_{1,1} is sent to the comparator in step 370 and the syndrome error estimate procedure ends in step 380.

An advantage of the blind TFCI detector is that the quality of a received vector can be estimated before turbo decoding the vector. The quality can then be used to determine the transmitted turbo-code in a variable message structure communication system. The quality can also be used to determine whether a vector has suffered from irrecoverable transmission errors and should be discarded before being processed by a turbo decoder.

The advantage of the process in saving memory is now explained in greater detail. For simplicity of notation, we omit hereafter the subscripts i,j. The BER estimation referred to above is based on the observation that the composition of the syndrome vector s is related to the number of transmission errors and to their distribution in the detected vector v. An optimum lower bound on the number of errors is the Hamming weight of the coset leader, i.e., the coset member with the minimum Hamming weight among all the vectors belonging to the coset identified by the syndrome vector. Unfortunately, selecting the Hamming weight of the coset leader as the estimated number of errors is usually not possible in the case of turbo codes using concatenated convolutional or block codes as their constituent codes, because the collection of cosets is vast.

For example, the UMTS convolutional codes composing the turbo code may have up to 2⁵¹²⁰ cosets. Storing all of those cases in a computer memory is practically impossible. Thus, a preferred embodiment makes use of a syndrome-based method of determining BER that has reasonable memory and computational requirements.

Since blind transport format detector 160 determines the BER of a received signal prior to the signal being decoded, it is especially useful for determining when a received vector should be transferred to a higher decision level due to a high BER. Thus, blind detector 160 can also include a threshold of the number of detectable errors. The threshold is set such that when it is exceeded, the turbo decoder is likely to fail in correct decoding. Hence, the vector can be transferred to a higher decision level to reduce the number of computations required by the turbo decoder.

Thus the present invention provides an apparatus and method for blind transport format decoding suitable for maximum a posteriori decoding, such as the case of turbo decoding.

The blind transport format decoding method of the present invention is particularly advantageous since it does not require fill decoding of a selection of candidate codes in order to determine which of the candidate codes is the most probable code thus being less processing intensive and as a result faster than prior art decoding methods.

It is appreciated that features described only in respect of one or some of the embodiments are applicable to other embodiments and that for reasons of space it is not possible to detail all possible combinations. Nevertheless, the scope of the above description extends to all reasonable combinations of the above described features.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. An apparatus for blind transport format detection of a received turbo coded data signal, the turbo code encoding the data signal being decomposable into at least two constituent codes, the apparatus comprising:
(a) a syndrome vector generator for generating syndrome vectors for each of the at least two constituent codes of a first candidate turbo code; and
(b) an error rate estimator for estimating an error rate of a received turbo coded data signal based on said syndrome vectors of at least one constituent code of the at least two constituent codes.

2. The apparatus of claim 1, further comprising:
(c) an adder for summing estimated error rates of the at least two constituent codes to thereby produce a first estimated error rate for said first candidate turbo code; and
(d) a selector for comparing said first estimated error rate of said first candidate turbo code with a second estimated error rate of a second candidate turbo code and for selecting a candidate turbo code of said first and second turbo codes having a lowest estimated error, said candidate turbo code selected being utilizable for decoding said turbo-coded data signal.

3. The apparatus of claim 2, wherein said second estimated error rate of a second candidate turbo code is obtained via turbo decoding.

4. The apparatus of claim 1, wherein encoding said turbo coded data signal comprises interleaving and concatenation of constituent codes.

5. The apparatus of claim 1, wherein the at least two constituent codes are convolutional codes.

6. The apparatus of claim 1, wherein the at least two constituent codes are block codes.

7. The apparatus of claim 1, wherein the turbo code encoding the data signal is an eight-state parallel concatenated convolutional code.

8. The apparatus of claim 1, wherein the turbo code encoding the data signal is a four state serial concatenated convolutional code.

9. The apparatus of claim 2, wherein said first and second candidate turbo codes are each associated with a different predetermined bit rate.

10. The apparatus of claim 1, further comprising a symbol by symbol detector for detecting the received turbo coded data signal symbol-wise for error estimation.

11. The apparatus of claim 2, further comprising a thresholder for comparing said lowest estimated error rate against a threshold and if said threshold is exceeded then not selecting said turbo-code having said lowest estimated error rate for decoding said received signal.

12. The apparatus of claim 1, wherein said error rate is a bit error rate (BER).

13. The apparatus of claim 10, further comprising a decomposer operable to decompose each symbol detected by said symbol by symbol detector into a symbol pair, each member of said pair corresponding to a different one of the at least two constituent codes.

14. The apparatus of claim 13, further comprising at least one pair of syndrome calculators operable to calculate a pair of said syndrome vectors based on said decomposed symbols output by said symbol by symbol detector and on an associated pair of parity check matrices.

15. The apparatus of claim 14, further comprising at least one pair of syndrome error estimators having at least one predetermined error pattern and further having a comparator operable to compare said at least one predetermined error pattern with said syndrome vector pair to produce an estimate of a bit error rate.

16. A method of blind transport format detection of a received turbo coded data signal comprising:
(a) receiving a turbo-coded data signal;
(b) detecting symbols from said data signal;
(c) decomposing said signals into signal pairs;
(d) determining syndrome vectors for each detected signal of said pair based on at least two candidate turbo-codes;
(e) comparing each syndrome vector with error patterns and thereby determining a bit error rate for each candidate turbo code; and
(f) selecting a candidate turbo code having a lowest bit error rate for decoding said data signal.

17. The method of claim 16, wherein encoding of said turbo coded data signal includes interleaving and concatenation.

18. The method of claim 17, wherein a turbo code of said turbo coded data signal includes at least two constituent codes.

19. The method of claim 18, wherein a constituent code of said at least two constituent codes is a convolutional code or a block code.

20. The method of claim 19, wherein said constituent code is an 8-state convolutional code with a block length of up to 5120 bits.

21. The method of claim 16, wherein said at least two candidate turbo codes are each associated with a different predetermined bit rate.

22. The method of claim 16, further comprising a step of comparing said lowest bit error rate selected against a threshold and if said threshold is exceeded then not selecting said candidate turbo code associated therewith for decoding said received signal.

23. The method of claim 16, wherein said step of calculating said pair of syndrome vectors is carried out based on said decomposed symbols output by said symbol by symbol detector and on an associated pair of parity check matrices.

24. The method of claim 23, wherein said error patterns are predetermined error patterns and wherein the method further comprises a step of comparing said at least one predetermined error pattern with said syndrome vector pair to produce an estimate of a bit error rate.

25. A method of blind transport format detection of a received turbo coded data signal comprising:
(a) receiving a turbo-coded data signal;
(b) detecting symbols from said data signal;
(c) decomposing said signal into a pair of signals;
(d) determining syndrome vectors for each signal of said pair of signals based on a first candidate turbo-code; and
(e) estimating an error rate of said turbo coded data signal based on said syndrome vectors of at least one signal of said pair of signals.

26. The method of claim 25, further comprising:
(f) summing said error rates of pair of signals to thereby produce a first estimated error rate for said first candidate turbo code;
(g) comparing said first estimated error rate of said first candidate turbo code with a second estimated error rate of a second candidate turbo code; and
(h) selecting a candidate turbo code of said first and second turbo codes having a lowest estimated error, said candidate turbo code selected being utilizable for decoding said turbo-coded data.

27. The method of claim 26, wherein said second estimated error rate of a second candidate turbo code is obtained via turbo decoding.
